(19) United States
(12) Patent Application Publication
(10) Pub. No.: US 2023/0301202 A1
(43) Pub. Date: Sep. 21, 2023

(54) INTERFACIAL ENGINEERING IN ARTIFICIAL PINNING CENTER-HIGH TEMPERATURE SUPERCONDUCTOR NANOCOMPOSITES

(71) Applicant: University of Kansas, Lawrence, KS (US)

(72) Inventor: Judy Z. Wu, Lawrence, KS (US)

(21) Appl. No.: 18/040,912

(22) PCT Filed: Aug. 24, 2021
(86) PCT No.: PCT/US21/47256

§ 371 Date: Feb. 7, 2023

Related U.S. Application Data
(60) Provisional application No. 63/069,932, filed on Aug. 25, 2020.

(51) Int. Cl. H10N 60/01; B82Y 30/00

(52) U.S. Cl. CPC H10N 60/0828; B82Y 30/00

(57) ABSTRACT

Superconducting nanocomposites are provided. One such nanocomposite comprises a high temperature superconductor (HTS); a plurality of artificial pinning centers (APCs) in the form of one-dimensional (1D) nanorods distributed throughout the HTS and oriented parallel to a c-axis of the HTS, each APC composed of a non-superconducting material and surrounded by the HTS, thereby forming an APC-HTS interface; and one or more repair regions composed of a repair material comprising a cation A, wherein a portion of the cation A of the repair material has diffused out of the one or more repair regions and into the HTS.

### CROSS-REFERENCE TO RELATED APPLICATIONS

The present application claims priority to U.S. provisional patent application No. 63/069,932 that was filed Aug. 25, 2020, the entire contents of which are incorporated herein by reference.

### REFERENCE TO GOVERNMENT RIGHTS

This invention was made with government support under DMR1508494 awarded by the National Science Foundation. The government has certain rights in the invention.

### BACKGROUND

Strong pinning of quantized magnetic vortices by nanoscale artificial pinning centers (APCs) can lead to significantly enhanced critical current density (J_{c}) in high temperature superconductors (HTSs), such as YaBa₂Cu₃O₇₋ₓ (YBCO) thin films and coated conductors. For example, self-assembled c-axis aligned one-dimensional (1D) APCs of various oxides, such as BaZrO₃ (BZO), BaSnO₃, BaHfO₃ (BHO) and double perovskites YBa₂(Nb/Ta)O₆, have been reported to provide strong correlated pinning of magnetic vortices when the applied magnetic field H is parallel to the 1D-APCs.

Despite the success in development of the 1D-APC/YBCO nanocomposites with improved pinning properties, dramatically different pining efficiencies of these 1D-APCs have been reported. For example, it has been found that BZO and BHO 1D-APCs of comparable diameters in the range of 5-6 nm have dramatically different pinning efficiencies. Specifically, as quantified by the peak pinning force density F_{p,max} (at Hₘₐₓ) and the ratio of Hₘₐₓ to the accommodation field H* determined from high-resolution transmission microscopy (HRTEM), the best reported F_{p,max} for BZO 1D-APC is consistently lower by up to a factor of 2 as compared to that of BHO 1D-APCs. In addition, Hₘₐₓ for the BZO 1D-APC/YBCO nanocomposite counts as only a fraction of the H*, indicating that a significant number of the BZO 1D-APCs observed in TEM are not efficient pinning centers.

### SUMMARY

Superconducting nanocomposites and methods of making and using the superconducting nanocomposites are provided.

A superconducting nanocomposite may comprise a high temperature superconductor (HTS); a plurality of artificial pinning centers (APCs) in the form of one-dimensional (1D) nanorods distributed throughout the HTS and oriented parallel to a c-axis of the HTS, each APC composed of a non-superconducting material and surrounded by the HTS, thereby forming an APC-HTS interface; and one or more repair regions composed of a repair material comprising a cation A, wherein a portion of the cation A of the repair material has diffused out of the one or more repair regions and into the HTS.

A method of making a superconducting nanocomposite may comprise depositing an APC-HTS nanocomposite material comprising a HTS and a non-superconducting material onto a surface of a substrate under conditions to form a plurality of APCs in the form of 1D nanorods distributed throughout the HTS and oriented parallel to a c-axis of the HTS, each APC composed of the non-superconducting material and surrounded by the HTS, thereby forming an APC-HTS interface; and depositing a repair material composed of a repair material comprising a cation A to form one or more repair regions, and under conditions so that a portion of the cation A of the repair material diffuses out of the one or more repair regions and into the HTS.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIG. 1A is a schematic of a cross-sectional view of superconducting nanocomposite according to an illustrative embodiment having two Ca_{0.3}Y_{0.7}Ba₂Cu₃O₇₋ₓ spacer layers and three BZO/YBCO layers. The Ca diffusion from the spacer layers to YBCO is illustrated by the arrows. FIG. 1B shows the c-axis elongated YBa₂Cu₃₋ₓCaₓO_{7-δ} unit cell as a consequence of the Ca/Cu replacement.

FIG. 2A shows a high-resolution cross-sectional STEM image of the BZO/Ca-Y123 doped multilayer YBCO thin film. The BZO and the BZO/YBCO areas are labeled. An enlarged view of the square area 200 was taken to examine the atomic lattice across the BZO/YBCO interface. An intensity line profile was conducted across the interface and showed that the doped BZO phase region had weaker intensity due to the lattice strain confinement effect. An enlarged view of the area 202 shows the atomic interface contact at the Ca-doped region and YBCO/STO interface under the <001> zone axis. Atomic arrangements were determined from FIGS. 3A, 3B, 3D, and 3E. Geometric phase analysis (GPA) of the ε_{yy} (out-of-plane) strain mapping of the HRSTEM image shown in FIG. 2A was also conducted. FIG. 2B shows the experimentally derived YBCO c-lattice spacing vs. distance (see arrow x in FIG. 2A)) from the BZO/YBCO interface for the area 204 without Ca-doped region and FIG. 2C shows the same for the area 206 with Ca-doped regions within the film.

FIGS. 3A, 3B, 3D, and 3E show the intensity line profiles across the YBCO/STO interface and Ca-doped regions within the doped multilayer YBCO thin film grown on STO (001) substrate. These are derived from the high-resolution STEM image of area 202 from FIG. 2A (now shown as FIG. 3C) showing the atomic interface contact at the Ca-doped region and YBCO/STO interface under the <001> zone axis. FIG. 3A is the intensity line taken along arrow A, FIG. 3B is the intensity line taken along arrow B, FIG. 3D is the intensity line taken along arrow D, and FIG. 3E is the intensity line taken along arrow E. The type of the atomic columns was noted based on their different line profile intensities. The dashed boxes in area 202 and FIGS. 3A and 3B correspond to the Ca-doped regions. The single dashed line indicates the STO substrate.

FIGS. 4A-4D show J_{c} vs. H (FIGS. 4A, 4C) and Fₚ vs H (FIGS. 4B, 4D) measured on single-layer (SL) and multilayer (ML) superconducting nanocomposite samples. The ML samples were 6 vol. % BZO/YBCO with CaY-123 spacer layers formed using different laser repetition rates (1, 2, or 4 Hz) but the same thicknesses (10 nm) of the CaY-123 spacer layers. The SL superconducting nanocomposite had no CaY-123 spacer layers. The plots were obtained with the magnetic field parallel to the c-axis, i.e., θ=0° (H//c-axis) at either 77K or 65 K.

FIGS. 5A-5D show J_{c} vs. H (FIGS. 5A, 5C) and Fₚ vs H (FIGS. 5B, 5D) measured on single-layer (SL) and multilayer (ML) superconducting nanocomposite samples. The ML samples were 6 vol. % BZO/YBCO with CaY-123 spacer layers formed using different thicknesses (5, 10, or 15 Hz) but the same repetition rate (4 Hz) of the CaY-123 spacer layers. The SL superconducting nanocomposite had no CaY-123 spacer layers. The plots were obtained with the magnetic field parallel to the c-axis, i.e., θ=0° (H//c-axis) at either 77 K or 65 K.

FIGS. 6A-6B show J_{c} vs. θ curves taken on a 6% ML 50 nm/10 nm-4 Hz sample and the S counterpart at 65 K and 5 T (FIG. 6A) and 9 T (FIG. 6B).

FIG. 7A shows the laser repetition rate (Hz) dependence of ratio of the F_{p,max}(ML)/F_{p,max}(SL) (left Y-axis) and ratio of the Hₘₐₓ(ML)/Hₘₐₓ(SL) (right Y-axis) measured at 77 K (solid) and at 65 K (open), on H//c-axis. FIG. 7B shows the ratio of the calculated N values of ML 50 nm/10 nm-2 Hz and the SL film with respect to the field oriented at H//c-axis at 77 K and at 65 K. FIG. 7C shows the magnetic field dependence of the N values of the 2% and 6% BZO/YBCO ML samples to the N values normalized to that of their SL counterparts at B//c and 65K. The ML samples were those of ML 50 nm/10 nm-2 Hz.

### DETAILED DESCRIPTION

Superconducting nanocomposites and methods of making and using the superconducting nanocomposites are provided. The superconducting nanocomposites comprise a high temperature superconductor (HTS) and a plurality of artificial pinning centers (APCs) distributed throughout the high temperature superconductor. Each APC is surrounded by HTS, thereby forming an APC-HTS interface. In the absence of the disclosed repair regions (further described below), dislocation defects are present at each APC-HTS interface. These defective APC-HTS interfaces negatively affect the superconducting properties of the HTS, including reducing its T_{c}. This, in turn, reduces the pinning potential height of the HTS and suppresses the pinning efficiencies of the APCs. The inventors have found that the damage to superconductivity such as that due to dislocation defects may be prevented or repaired by including one or more repair regions comprising a repair material in the superconducting nanocomposite according to the methods disclosed herein. These superconducting nanocomposites are characterized by improved APC pinning efficiencies as compared to comparative superconducting nanocomposites without the one or more repair regions.

In one aspect, superconducting nanocomposites are provided. In embodiments, a superconducting nanocomposite comprises a HTS, a plurality of APCs distributed throughout the HTS, each APC surrounded by the HTS and forming an APC-HTS interface, and one or more repair regions composed of a repair material. The one or more repair regions may be in direct contact with at least one APC-HTS interface. The HTS, the plurality of APCs, and the one or more repair regions are physically and chemically distinct from one another in the superconducting nanocomposite as evidenced by TEM and elemental mapping.

A variety of high temperature superconductors may be used in the superconducting nanocomposites. In embodiments, the HTS is a rare-earth barium copper oxide, e.g., (RE)Ba₂Cu₃O₇₋ₓ, wherein the RE is selected from Sc, Y, and the lanthanides. In embodiments, the HTS is YBa₂Cu₃O₇₋ₓ (YBCO).

The APCs distributed throughout the HTS of the superconducting nanocomposites are composed of a non-superconducting material. Generally, the non-superconducting material is one which has a lattice mismatch with the selected HTS which tends to lead to the formation of dislocation defects at the interface formed between the selected HTS and the selected non-superconducting material. This lattice mismatch may be at least 6%, at least 6.5%, at least 7%, at least 7.5%, or at least 8%. The non-superconducting material may be a perovskite, including a single perovskite having formula ABO₃. An illustrative such perovskite is BaZrO₃ (BZO). Other illustrative perovskites include YBa₂NbO₆, BaSnO₃, BaHfO₃, SrZrO₃, SrHfO₃, CaSnO₃, and CaHfO₃.

The APCs are characterized by their morphology, including their shapes, sizes, orientations, and density in the HTS of the superconducting nanocomposites. This morphology can depend upon the compositions of the selected HTS and the selected non-superconducting material, the amount of the non-superconducting material in the HTS, as well as the conditions used to form the superconducting nanocomposites. The selected morphology can depend upon the desired superconducting properties for the superconducting nanocomposite and as such, its desired application.

In embodiments, the APCs are one-dimensional (1D) nanostructures having two nanoscale dimensions which are of similar magnitude and the third dimension (which may also be nanoscale) significantly greater than the other two nanoscale dimensions. In embodiments, the 1D nanostructures are 1D nanorods characterized by a diameter. However, “nanorod” is not intended to be limiting to nanostructures having perfectly circular or elliptical cross-sections. In addition, 1D nanostructures having square or rectangular cross-sections may be used. The diameter (or width) may be less than 100 nm, less than 50 nm, less than 10 nm, less than 8 nm, less than 6 nm, or in the range of from 1 to 100 nm. The diameter/width may be an average value as determined from a representative number of 1D nanorods/nanostructures.

The 1D nanostructures may be characterized by their orientation/alignment and distribution within the HTS. In embodiments, the 1D nanostructures are aligned parallel to a major crystalline axis of the HTS, e.g., the c-axis of the HTS. Thus, individual 1D nanostructures within the plurality of 1D nanostructures are aligned parallel to one another. They are also separated from one another and may be characterized by a center-to-center distance (which may also be an average value). The center-to-center distance may be in a range of from 5 nm to 100 nm, from 5 nm to 50 nm, from 5 nm to 20 nm, from 8 nm to 16 nm, or from 10 nm to 14 nm.

The amount of the non-superconducting material in the HTS (given as a volume %) may vary, but is generally a small amount. In embodiments, the amount is in a range of from 0.5 vol % to 20 vol %, 1 vol % to 10 vol %, from 2 vol % to 8 vol %, or from 3 vol % to 7 vol %.

The repair region(s) in the superconducting nanocomposite are composed of a repair material. The composition of the repair material is chemically distinct from that of the selected HTS and the selected APC (non-semiconducting) material. The repair material is one which is capable of improving superconductivity properties from damage such as that due to dislocation defects at the APC-HTS interfaces. Thus, the selection of the repair material depends upon the selected HTS/selected APC. In embodiments in which the HTS is (RE)Ba₂Cu₃O₇₋ₓ and the APC is composed of one of the perovskites listed above, the repair material may be composed of (A_{y})(RE_{1-y})Ba₂Cu₃O₇₋ₓ. In this formula, an amount (y) of the RE of the HTS is replaced by an amount of a different cation (A). By way of illustration, when the HTS is YBCO and the APC is composed of BZO, a suitable repair material is Ca_{y}RE_{1-y}BCO, which includes Ca_{y}Y_{1-y}BCO. The amount (y) may vary, but embodiments it is in a range of from 0.01 to 0.5. The replacement of “Y” (or in general, a rare earth element) by “Ca” or another “A” element results in REBCO superconductor “positively charged hole overdoped” or with extra-oxygen. This means other Ca-containing repair materials, or in general other repair materials with element A of similar functionality to Ca, will work to provide Ca (or cation A) to diffuse into the surrounding lattice (composed of the selected HTS/selected APC) to prevent or repair damage such as dislocation defects. Even insulators (non-superconductors) comprising Ca (or cation A) may be used.

The repair regions may be characterized by their shapes, sizes and densities. These parameters may vary depending upon the selected morphology for the APCs. These parameters may also be selected to optimize the diffusion of cation A into the surrounding lattice. Diffusion can reduce the damage to superconductivity, e.g., caused by dislocation defects, at the APC-HTS interface. As described in the Example below, this can occur by the replacement of cations in the HTS lattice by cation A of the repair material to relieve strain by adjusting (e.g., elongating) the HTS lattice. By way of illustration, the ˜7.7% lattice mismatch between BZO and YBCO may be reduced to ˜1.4% by using Ca_{y}Y_{1-y}BCO repair regions as described in the Example, below. This, in turn, increases the T_{c} of the HTS column surrounding the APC (defined as the interface T_{c}, or T_{cI}) and hence, increases the APC pinning efficiency. However, diffusion can also have a negative effect involving reducing the T_{c} of the superconducting nanocomposite and hence decrease APC pinning efficiency. Prior to the experiments described in the Example below, it was not reasonably predictable whether it would be possible to sufficiently balance the competing effects associated with diffusion in order to improve superconducting properties. Similarly, the magnitude of improvement in the APC pinning efficiencies of the superconducting nanocomposites as demonstrated in the Example, below, was unexpected in view of the competing effects.

In embodiments, the repair regions are in the form of layer(s), which may be embedded within the HTS-APC. The use of layers of the repair materials allows direct contact with multiple APC-HTS interfaces, including the HTS columns surrounding the 1D APCs, at one time. Such layers may be characterized by a thickness (which may be an average value). One or more such layers may be used. As noted above, these parameters may be selected to optimize diffusion of cation A into the surrounding lattice, i.e., balance the competing effects described above. In embodiments, the layer(s) have an average thickness in a range of from 1 nm to 20 nm, from 2 nm to 15 nm, from 1 nm to 10 nm, from 5 nm to 10 nm, from 1 nm to 5 nm, or from 1 nm to 3 nm. In embodiments, more than one layer is included in the superconducting nanocomposite. The layer(s) of the repair materials may be oriented parallel to the plane of the superconducting nanocomposite. For insulating (non-superconducting) repair materials, the layers can be ab-plane aligned.

The superconducting nanocomposites may be in the form of a film disposed on an underlying substrate. The film may be characterized by a thickness (which may be an average value). For superconducting nanocomposites in which the repair regions are in the form of layer(s) separated by layers of HTS-APC, the film thickness refers to an overall thickness. Film thickness in a range of from 50 nm to 5000 nm, from 100 nm to 500 nm, from 100 nm to 250 nm, or from 150 nm to 200 nm may be used. However, films having multiple layers of repair material embedded between multiple layers of HTS-APC of thickness in the range of 10 nm-1000 nm may be used, resulting in greater thicknesses, e.g., at least 1 μm, at least 5 μm, at least 10 μm. Other thicknesses for the individual layers of HTS-APC include from 25 nm to 100 nm, from 30 nm to 90 nm, from 35 nm to 80 nm, from 40 nm to 70 nm, and from 40 nm to 60 nm. A variety of substrates may be used, depending upon the desired application.

The superconducting nanocomposites may be characterized by certain properties, especially those related to the pinning efficiency. Such properties include a peak pinning force density (F_{p, max}) and ratio of the F_{p, max} location Hₘₐₓ to the accommodation field H* (Hₘₐₓ/H*). This ratio can be estimated based on the areal density of the 1D APCs which can be obtained using electron microscopy. These properties and techniques for measuring these properties are described in the Example, below. As noted above, the inventors have found that the pinning ability of the APCs can, in fact, be significantly improved via the repair material of the repair region(s). This may be achieved even though at least some dislocation defects remain in the repaired superconducting nanocomposites. In embodiments, the superconducting nanocomposites exhibit F_{p, max} and/or Hₘₐₓ/H* values that are greater than the respective values for comparative nanocomposites. By “comparative nanocomposites,” it is meant superconducting nanocomposites that have the same composition/structure as the superconducting nanocomposites except that they do not include the repair material/repair region(s). In embodiments, the superconducting nanocomposites exhibit a F_{p, max} that is a factor of at least 1.5, 2, 3, 4, 5, or 6 greater than that of a comparative nanocomposite. In embodiments, the superconducting nanocomposites exhibit a Hₘₐₓ/H* that is at least 30%, at least 35%, at least 40%, or at least 45% greater than that of a comparative nanocomposite. These values may refer to a particular temperature, e.g., 65 K or 77 K.

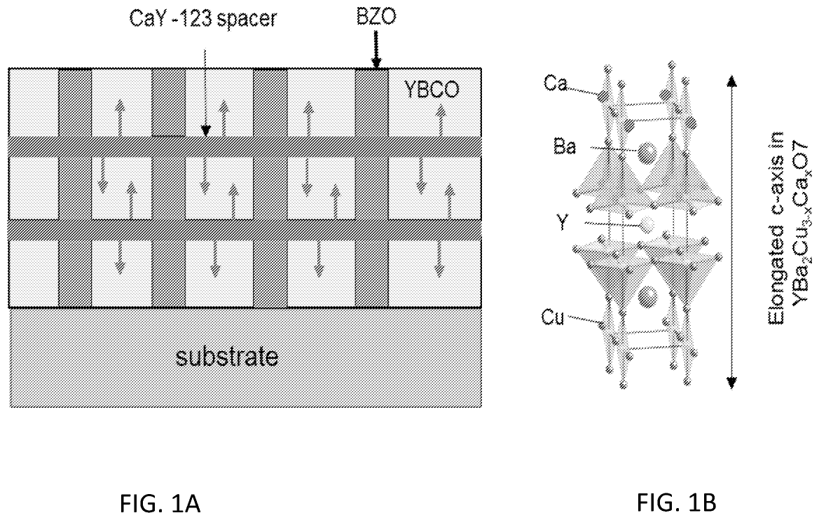

An illustrative superconducting nanocomposite is shown in FIG. 1A and is described in more detail in the Example, below.

Methods of making the superconducting nanocomposites are also provided. These methods effectively provide a technique for preventing or repairing damage to superconductivity due to, e.g., dislocation defects at APC-HTS interfaces, thereby improving the pinning abilities of the APCs and the superconducting properties of the HTS nanocomposites. In embodiments, such a method comprises depositing an APC-HTS nanocomposite material comprising a HTS and a non-superconducting material onto a surface of a substrate under conditions to form (e.g., via self-assembly) a plurality of APCs distributed throughout the HTS, each APC surrounded by the HTS and forming an APC-HTS interface. The method further comprises depositing a repair material on the as-deposited APC-HTS nanocomposite material to form one or more repair regions. Each repair region may be in direct contact with at least one APC-HTS interface. The conditions used to deposit the repair material are selected to balance the competing effects of the diffusion of cation A into the surrounding lattice as described above.

The deposition may be carried out using a physical vapor deposition technique, e.g., pulsed laser deposition (PLD) or magnetron sputtering. PLD may be carried out using an alternate target technique in which the PLD laser alternates between two targets (one comprising the APC-HTS nanocomposite material and the other comprising the repair material). The conditions for depositing the APC-HTS nanocomposite material and the conditions for optimizing diffusion may include the repetition rate of the PLD laser (determining growth rate per unit time), laser beam spot size and energy density on each target (determining growth rate per laser pulse), substrate temperature, and heating time. As described in the Example, below, the inventors have found that these parameters may be tuned to optimize diffusion of cation A into the surrounding lattice. Without wishing to be bound to a particular theory, it is believed that the timing of the diffusion is particularly important, including to reduce APC-HTS interfacial strain before dislocation defects occur. This is further described in the Example, below.

The selection of parameters depends upon the composition of the APC-HTS composite/repair material. The specific optimal parameters also depend upon the thickness of the repair region (determining the concentration gradient of the repair material), the thickness of the APC-HTS composite (determining the minimum diffusion length required), and concentration of non-superconducting material (e.g., BZO). By way of illustration, an optimal repetition rate for BZO/YBCO (APC-HTS) using Ca_{0.3}Y_{0.7}BCO as the repair material is 1-4 Hz and an optimal repair material thickness is 1-10 nm. As shown in the Example, below, a repair material thickness of 10 nm and a repetition rate of 2 Hz was found to achieve an unexpectedly high value of F_{p, max} of about 160 GN/m³ at Hₘₐₓ ˜8 T and 65 K. However, allowing for different combinations of materials, in general, repetition rates from 0.1 Hz to 100 Hz, 0.1 Hz to 50 Hz, and 0.1 Hz to 25 Hz may be used. Repair material thicknesses of 10 nm to 20 nm may also be used.

Other methods may be used to make the superconducting nanocomposites These may include sputtering, evaporation, solution-based process, and inkjet printing. Cation A (e.g., Ca) doping does not need to be in situ, so techniques such as inkjet printing of the various layers followed by post annealing may be used.

Methods of using the superconducting nanocomposites are also provided. In embodiments, such a method comprises exposing the superconducting nanocomposite to a magnetic field at a temperature below the superconducting nanocomposite's T_{c}. Under these conditions, the superconducting nanocomposite is capable of perfect conduction and the APCs are capable of generating pinning forces to oppose vortexes of quantized magnetic flux that may arise in the HTS. The magnetic field may be oriented parallel to the c-axis of the HTS of the superconducting nanocomposite.

### EXAMPLE

### Introduction

One-dimensional c-axis aligned BaZrO₃ (BZO) nanorods are regarded as strong artificial pinning centers (1D-APCs) in YaBa₂Cu₃O₇₋ₓ (YBCO) films. However, a microstructure analysis revealed a highly defective, oxygen-deficient YBCO column of 1-2 nm in thickness around the BZO 1D-APCs due to the large lattice mismatch of ˜9% between the BZO (3a=1.26 nm) and YBCO (c=1.17 nm). Considerably reduced superconducting transition temperature (T_{c}) and hence reduced pinning potential height in this column has been confirmed to result in much lower pinning efficiency of the BZO 1D-APCs as compared to BaHfO₃ (BHO) 1D-APCs. This Example presents a novel approach of dynamic Ca/Cu replacement on tensile strained YBCO lattice immediately after the BZO 1D-APCs formation to induce elongation of the YBCO lattice along the c-axis to prevent the interfacial defect formation by reducing the BZO/YBCO lattice mismatch. Specifically, this is achieved by inserting thin Ca_{0.3}Y_{0.7}Ba₂Cu₃O₇₋ₓ (CaY-123) spacers to facilitate calcium diffusion into the YBCO lattice in 2-6 vol. % BZO+YBCO nanocomposite films. An YBCO elongated c-axis up to 1.24 nm via Ca/Cu replacement on single Cu—O planes of YBCO and a defect-free, coherent BZO 1D-APC/YBCO interface are confirmed in high-resolution transmission electron microscopy and elemental distribution analyses. Surprisingly, up to a five-fold enhancement of J_{c} (H) at magnetic field H=9.0 T//c-axis and 65-77 K was obtained in the multilayer (ML) samples as compared to their 6 vol. % BZO/YBCO single-layer (SL) counterparts. This has led to a record high pinning force density Fₚ together with significantly enhanced Hₘₐₓ at which Fₚ reaches its maximum value F_{p,max} for BZO 1D-APCs at H//c-axis. At 65 K, F_{p, max} ˜157 GN/m³ and Hₘₐₓ ˜8.0 T in the 6 vol. % BZO/YBCO ML samples. This is a significant and unexpected enhancement over F_{p, max} ˜36.1 GN/m³ and Hₘₐₓ ˜5.0 T on the 6 vol. % BZO/YBCO SL counterparts. This result illustrates not only the critical importance of the BZO 1D-APC/YBCO interface in the pinning efficiency of the BZO 1D-APCs, but also provides a facile scheme to repair the interface for higher pinning efficiency.

As discussed in detail below, this Example investigates 6 vol. % BZO/YBCO nanocomposite films consisting of three 50 nm thick 6 vol. % BZO/YBCO layers separated by two CaY-123 spacers of thicknesses in the range of 5-15 nm. The CaY-123 spacers serve as the Ca reservoirs while the Ca diffusion and cation replacement on YBCO is driven by the strain on the BZO/YBCO lattice. A microstructure analysis of these multilayer (ML) samples confirms the Ca/Cu replacement and consequent elongation of the c-axis of YBCO up to ˜1.24 nm, resulting in much reduced strain on BZO/YBCO. Most excitingly, the formation of interfacial defects becomes negligible, leading to a highly coherent BZO 1D-APC/YBCO interface. In comparison with the comparative 6 vol. % BZO/YBCO nanocomposite single-layer (SL) samples, remarkably enhanced J_{c}(H) at high magnetic fields exceeding 1-3 T is obtained for the ML samples. At 9.0 T, a five folds enhancement of the J_{c} is obtained in the temperature range of 65-77 K, which can be attributed to the much enhanced pinning efficiency of the BZO 1D-APCs with coherent interfaces with the YBCO lattice as illustrated in both enhanced Fₚ and Hₘₐₓ.

### Methods

Calcium doped, BZO plus YBCO multilayer films were deposited using pulsed laser deposition (PLD) from two targets, one composed of Ca_{0.3}Y_{0.7}Ba₂Cu₃O₇₋ₓ (CaY-123) and the other composed of 6 vol. % BZO/YBCO. Multilayer (ML) films of total thickness in a range of from 160 nm to 170 nm were fabricated using an alternate-target method. The 1^{st}, 3^{rd} and 5^{th} layers, each of approximately 50 nm thickness, were made up of 6 vol. % BZO/YBCO while the 2^{nd} and 4^{th} layers were made up of CaY-123 of from approximately 5 nm to 15 nm in thickness. Comparative single-layer (SL) films of 6 vol. % BZO/YBCO (no CaY-123) having similar thickness (˜160 nm) were also fabricated to compare the effect of calcium doping in the ML films.

In this Example, the films having the 50 nm thick 6 vol. % BZO/YBCO layers and the CaY-123 spacer layers are referred to as ML samples (or films). Some ML samples were prepared using the same thickness of the CaY-123 spacer layers (10 nm) but different PLD laser repetition rates (RR), including 1 Hz, 2 Hz, and 4 Hz. These are referred to as ML 50 nm/10 nm-1 Hz, ML 50 nm/10 nm-2 Hz and ML 50 nm/10 nm-4 Hz, respectively. Other ML samples were prepared using the same RR (4 Hz), but different thicknesses of the CaY-123 spacer layers, including 5 nm, 10 nm, and 15 nm. These are referred to as ML 50 nm/5 nm-4 Hz, ML 50 nm/10 nm-4 Hz, and ML 50 nm/15 nm-4 Hz, respectively. The comparative films formed entirely of 6 vol. % BZO/YBCO (no CaY-123 spacer layers) are referred to as SL samples (or films). All ML and SL films were prepared on (100) SrTiO₃ (STO) single crystal substrates at a substrate temperature of 825° C. in a 300 mTorr oxygen (O₂) environment. After deposition, the films were annealed for about 30 minutes dwell time at 500° C. in 1 atm of O₂.

Film thicknesses were measured using a Tencor P-16 profilometer. For electrical transport measurement, Ag contact pads were sputtered on the samples through a shadow mask. The samples were then patterned using standard photolithography (Leica) to create two microbridges of length ˜500 μm and width of 20 and 40 μm respectively. The details of the pattering and sample wiring for the transport measurement can be found in Wang, X., et al., Journal of Applied Physics, 2010. 108 (11): p. 3911 and Chen, S., et al., IEEE Transactions on Applied Superconductivity, 2017. 27(4): p. 1-5. The samples were mounted on a oxygen-free Cu stage using Ag paste and resistance-temperature (R-T) and current-voltage (I-V) characteristic curves were measured using an Agilent nanovoltmeter as function of temperature T (65K-77 K) and the magnetic field H (up to 9.0 T) parallel to the thickness of the film in a Quantum Design Ever-Cool II Physical Property Measurement System (PPMS). In order to minimize the heating at high currents, a pulsed current source was used with a pulse width of ˜500 ms for the I-V curves. J_{c} was determined by applying 1 μV/cm standard criterion. (See Gautam, B., et al., Superconductor Science and Technology, 2017; Chen, S., et al., IEEE Transactions on Applied Superconductivity, 2017. 27(4): p. 1-5; and Emergo, R. L. S., et al., Superconductor Science and Technology, 2010. 23(11): p. 115010.) X-ray diffraction (XRD) θ-2θ patterns were taken using a Bruker D8 Discover diffractometer to determine the c-axis lattice constant of the films. Transmission electron microscopy (TEM) and scanning transmission electron microscopy (STEM) (under a high angle annular dark field mode (HAADF)) were taken using Thermo Fisher Scientific TALOS F200X TEM system with a point-to-point resolution of 1.6 Å. High-resolution STEM images were taken on Thermo Fisher Scientific Themis-Z TEM system, a new generation of aberration-corrected microscope with the STEM resolution down to 63 pm operated at acceleration voltage of 300 kV with combined correctors. A Digital Micrograph plug-in (DM 1.8.3 package, HRTEM Research Inc.) was used for geometric phase analysis (GPA). The cross-sectional TEM samples were prepared by a standard procedure, including manual grinding, polishing, dimpling and a final ion milling step (PIPS 691 precision ion polishing system, Gatan Inc.).

### Result and Discussion

FIG. 1A illustrates schematically the cross-sectional view of the 6 vol. % BZO/YBCO ML nanocomposite samples, consisting of three 6 vol. % BZO/YBCO layers stacking alternately with the two CaY-123 spacers. The arrows illustrate schematically the Ca diffusion into YBCO. Considering that the lattice constant of BZO is larger than that of the c-axis of YBCO with ˜8% of lattice mismatch, Ca/Cu replacement would occur on the YBCO lattice due to the presence of a tensile strain in the c-axis after the BZO 1D-APCs form in the BZO/YBCO nanocomposite films (FIG. 1B).

The microstructure of the single and multilayer BZO doped layered YBCO films were characterized using a Cs-corrected transmission electron microscope (TEM) and scanning transmission electron microscopy (STEM). Low-mag and high-resolution cross-sectional STEM images of the 6 vol. % BZO doped single layer YBCO film were obtained. The doped BZO showed clear nanocolumns embedded in the YBCO film matrix. The HRSTEM images showed the high-quality epitaxial growth of the cubic BZO dopants and the layered structure of YBCO. A distorted YBCO lattice is caused by the strain effect at the BZO/YBCO interface. The morphology and element distribution of the BZO/CaY-123 doped multilayer YBCO film were examined. Selected area electron diffraction (SAED) patterns confirmed the epitaxial growth of YBCO (000l) on the STO (001) substrate. From the energy-dispersive X-ray spectroscopy (EDS) mapping results, Ca was found to be enriched at specific YBCO atomic planes as discussed in detail below.

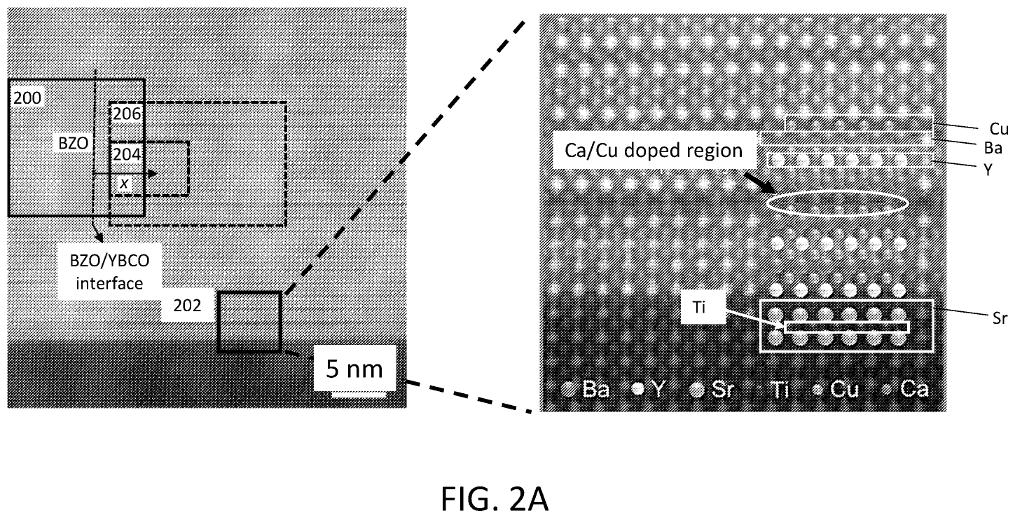

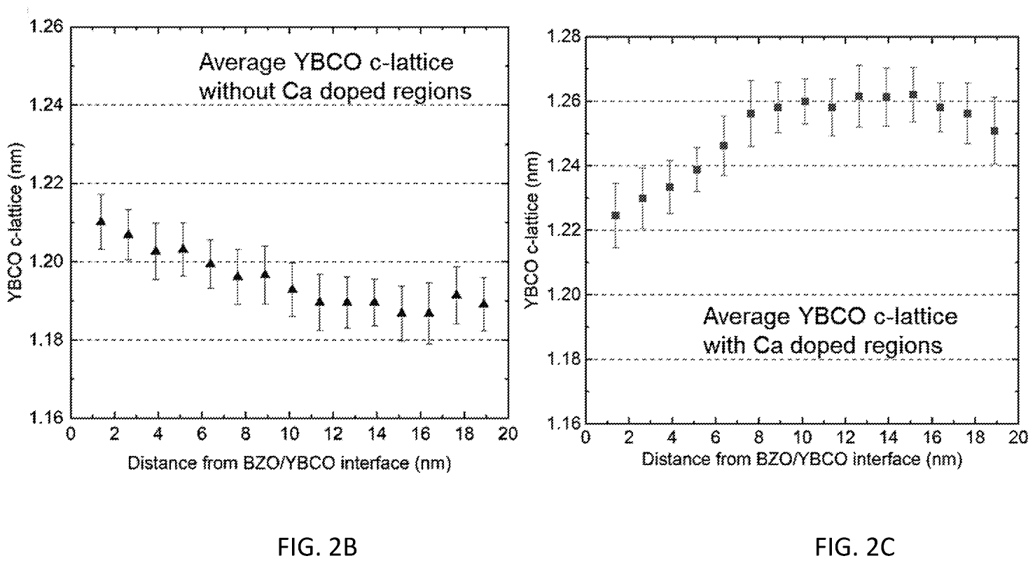

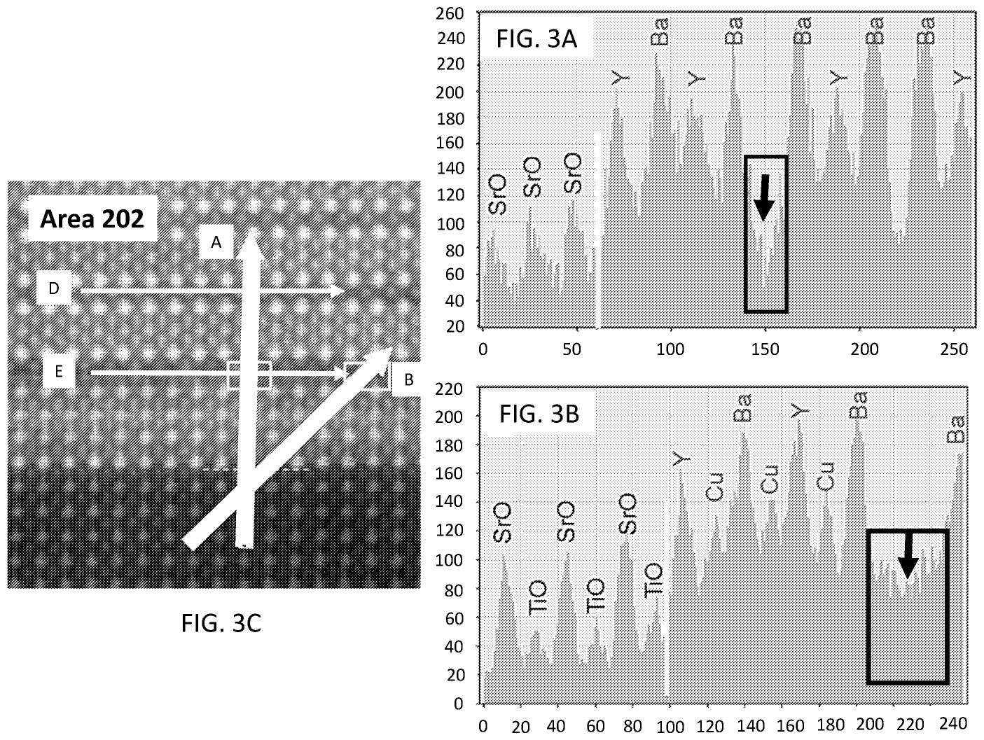

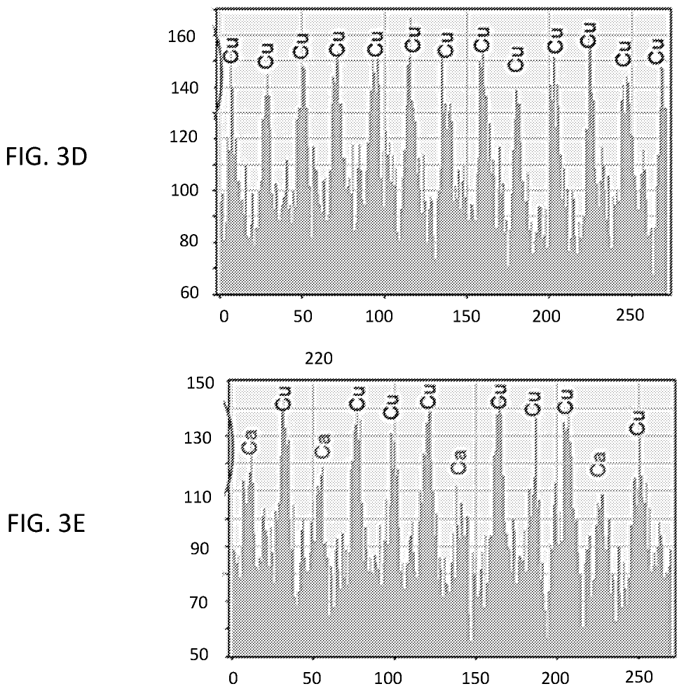

Based on the high-resolution STEM-HAADF image shown in FIG. 2A of the BZO/Ca-Y123 doped multilayer YBCO thin film, an intensity line profile was conducted to examine the phase distribution across the BZO/YBCO heterointerface. The clear phase separation between BZO and YBCO was observed from the different contrasts in the line profile, where the lower intensity of BZO phase is attributed to a strain-confinement effect. An enlarged view of area 202 is also shown to the right of FIG. 2A, showing the atomic interface contact at the Ca-doped region and YBCO/STO interface under the <001> zone axis. The high-resolution Cs-corrected STEM image provided directly interpretable atomic arrangements of the cations at the heterostructure interfaces. Specifically, four intensity line profiles were performed across the YBCO/STO interface and Ca-doped regions, as the vertical (A), inclined (B), and horizontal (C, D) arrows indicate in the image of area 202 shown to the left of FIGS. 3A-3B as FIG. 3C. Due to the relationship between STEM image intensity (I) and atomic number (Z), i.e. I∝Z^{1.7}, the atomic columns were identified based on their different line profile intensities, as shown in FIGS. 3A-3B. The Ca-doped regions are represented by the wider low intensity ranges in the line profiles, as denoted by the arrows and dashed boxes. The projected atomic arrangements of YBCO, STO and Ca doped layer lattices are superimposed on the image of area 202 to the right of FIG. 2A.

To further explore the lattice vs. strain relationship in the BZO/Ca-Y123 doped multilayer YBCO film, the geometric phase analysis (GPA) of the out-of-plane (ε_{yy}) strain mapping of the HRSTEM image of FIG. 2A was conducted. It is clear that the BZO columns and Ca-doped regions within the film show larger c-lattice spacing due to the strain effect. Furthermore, the local strain effect can be quantified by measuring the c-axis variation of YBCO in the HRSTEM image. FIG. 2B shows the YBCO c-lattice as a function of the distance from BZO/YBCO interface, where the c-axis spacing was calculated by averaging 5 unit cells in the corresponding area 204 shown in the HRSTEM image of FIG. 2A. It can be seen that the c-lattice of YBCO is gradually decreases as it moves away from the heterointerface because of the gradually relieved interfacial strain. However, by including some Ca-doped regions, as is the case with the larger corresponding area 206 in the HRSTEM image of FIG. 2A, the average c-lattice of YBCO is found to increase to maximum then be relatively constant as the distance from the heterointerface increases. This can be explained by the compensation between the interfacial strain relaxation at the YBCO/BZO heterointerfaces and the additional strain induced by Ca-doping effects. The average YBCO c-lattice values reach the maximum of ˜1.24 nm and then keep relative constant when these two effects are compensated.

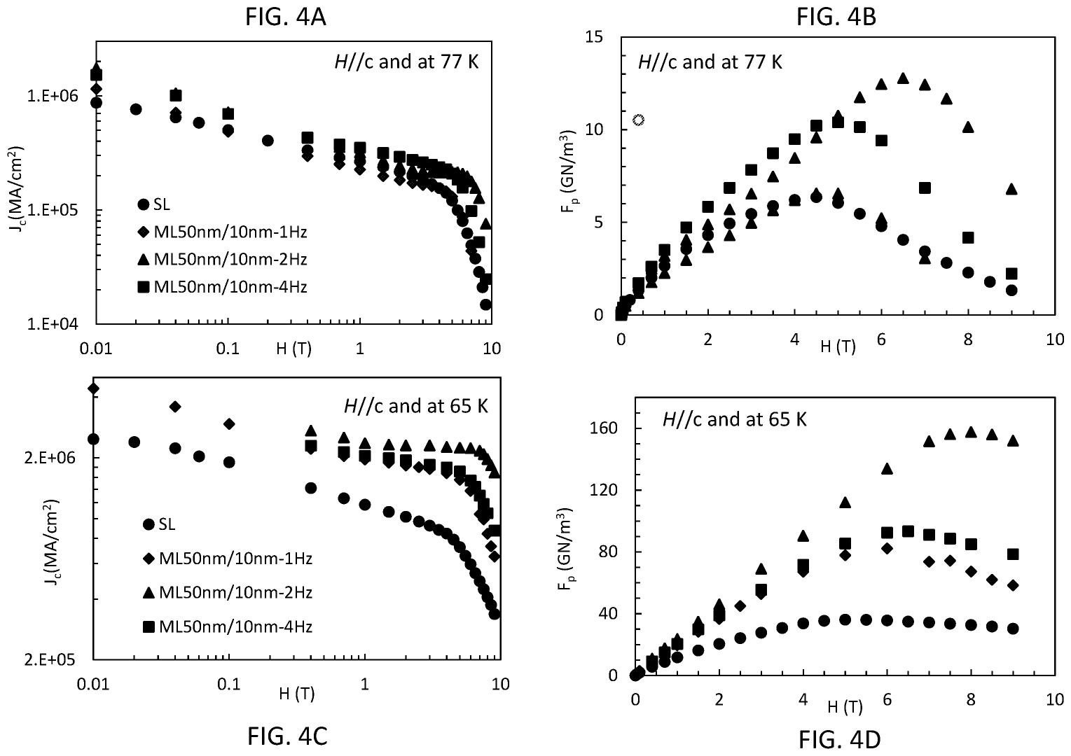

FIGS. 4A-4D compare the J_{c}(H) and Fₚ(H) curves of three ML samples with their SL reference sample at 77 K and 65 K, respectively. The three ML samples were 6% BZO/YBCO ML 50 nm/10 nm-1 Hz, 6% BZO/YBCO ML 50 nm/10 nm-2 Hz, and 6% BZO/YBCO ML 50 nm/10 nm-4 Hz. Thus, the three ML samples had CaY-123 spacer layers of the same thickness but formed using different PLD repetition rates of 1 Hz, 2 Hz, and 4 Hz. This means that the PLD growth time reduced monotonically to 50% and 25% in the 2 Hz and 4 Hz samples as compared to that of the 1 Hz sample. At 77 K, the three ML samples have self-field J_{c} exceeding 1.0 MA/cm², which is slightly higher than that for the SL reference sample. The slightly lower self-field J_{c} for the SL sample is consistent with the strain at 6 vol. % BZO doping that typically reduces T_{c} of the BZO 1D-APC/YBCO nanocomposite monotonically with increasing BZO content. For this specific SL sample, the T_{c} was 86.9 K (see Table 1, below). Interestingly, this T_{c} value is at least 1.9 K higher than the T_{c} values of the ML counterparts of 83.5 K (1 Hz), 84.0 K (2 Hz) and 85.0 K (4 Hz) as also shown in Table 1. At low H fields up to 1-2 T, the four samples have comparable J_{c}(H) and Fₚ(H) values. At higher H fields the 6% BZO/YBCO ML 50 nm/10 nm-1 Hz sample has similar J_{c}(H) and Fₚ(H) values to that of the SL sample at 77 K, possibly due to the T_{c} effect considering its T_{c} ˜83.5 K is fairly close to 77 K. However, the other two ML samples have visibly higher J_{c}(H) and Fₚ(H) values at higher H fields at 77 K (see FIGS. 4A, 4B). This cannot be attributed to T_{c} effect in view of the significantly higher J_{c}(H) and Fₚ(H) values for all three ML samples at 65 K as compared to their SL counterpart in the entire range of the field up to 9.0 T (FIGS. 4C, 4D) despite their lower T_{c}'s as expected from Ca-doping. Thus, the result confirms the enhanced pinning efficiency of BZO 1D-APCs achieved in the ML samples.

TABLE 1
Summary of parameters such as critical temperature (T_{c}), F_{p, max,} Hₘₐₓ, and alpha values of undoped YBCO,
6 vol. % BZO/YBCO, and multilayer (ML) 6 vol. % BZO/YBCO films having from 5 nm to
15 nm of CaY-123 and formed using a laser repetition rate of 1, 2, and 4 Hz.

| | | F_{p.max} (H//c-axis) | | Hₘₐₓ (H//c-axis) | | Alpha (α) values at H//c-axis | |
|---|---|---|---|---|---|---|---|
| Sample ID | T_{c,onset} (K) | 77 K | 65 K | 77 K | 65 K | 77 K | 65 K |
| YBCO | 89.0 | 7.98 | 54.83 | 2.0 | 5.0 | 0.49 | 0.24 |
| 6% BZO/YBCO | 86.9* | 6.36 | 36.14 | 4.5 | 5.0 | 0.28 | 0.21 |
| 6% BZO ML50 nm/10 nm-1 Hz | 83.5 | 6.55 | 82.20 | 4.5 | 6.0 | 0.31 | 0.18 |
| 6% BZO ML50 nm/10 nm-2 Hz | 84.0 | 12.77 | 157.70 | 6.5 | 8.0 | 0.34 | 0.14 |
| 6% BZO ML50 nm/10 nm-4 Hz | 85.0 | 10.40 | 93.35 | 5.0 | 6.5 | 0.29 | 0.13 |
| 6% BZO ML50 nm/15 nm-4 Hz | 85.0 | 10.15 | 100.39 | 5.0 | 6.0 | 0.27 | 0.24 |
| 6% BZO ML50 nm/5 nm-4 Hz | 85.0 | 16.55 | 144.34 | 5.0 | 6.5 | 0.26 | 0.12 |

Asterisk (*) indicates the T_{c,onset} value for the single layer (SL) film (no CaY-123). At 65 K, alpha values of ML films are calculated in the different field range of 0.4 T to few Teslas depending on the linear region.

Quantitatively, the J_{c}(H) enhancement in ML samples increases with the H field. For example, a five-fold higher J_{c} (at 9.0 T) can be observed when comparing the 6% BZO/YBCO ML 50 nm/10 nm-2 Hz (optimal among the three ML samples of FIGS. 4A-4D) and the SL reference sample at both 65 K and 77 K. Furthermore, the F_{p, max} of the ML samples is significantly higher than that of the SL sample. At 77 K, the enhancement is up to 100%. At 65 K, the enhancement is about 4.3 times. It should be noted that the F_{p, max} of ˜157 GN/m³ at 65 K represents the best reported so far on BZO 1D-APC/YBCO nanocomposites. The enhanced pinning efficiency of individual BZO 1D-APCs and the concentration of the activated strong BZO 1D-APCs are further illustrated in the enhanced Hₘₐₓ values in the ML samples as compared to the SL reference sample. Specifically, the Hₘₐₓ values are 4.5 T at 77K and 5.0 T at 65 K for the SL sample. Compared to the accommodation field H* ˜14.3 T estimated from TEM determined spacing between the BZO 1D-APCs, the low Hₘₐₓ values suggest a significant portion of ˜68% of the formed BZO 1D-APCs are not efficient in pinning at 77 K in the SL sample. However, in the ML samples, they are improved up to 6.5 T (77 K) and 8.0 T (65 K), respectively (see Table 1), indicating a substantial portion of the BZO 1D-APCs are activated in the ML samples and contribute to pinning at high H fields.

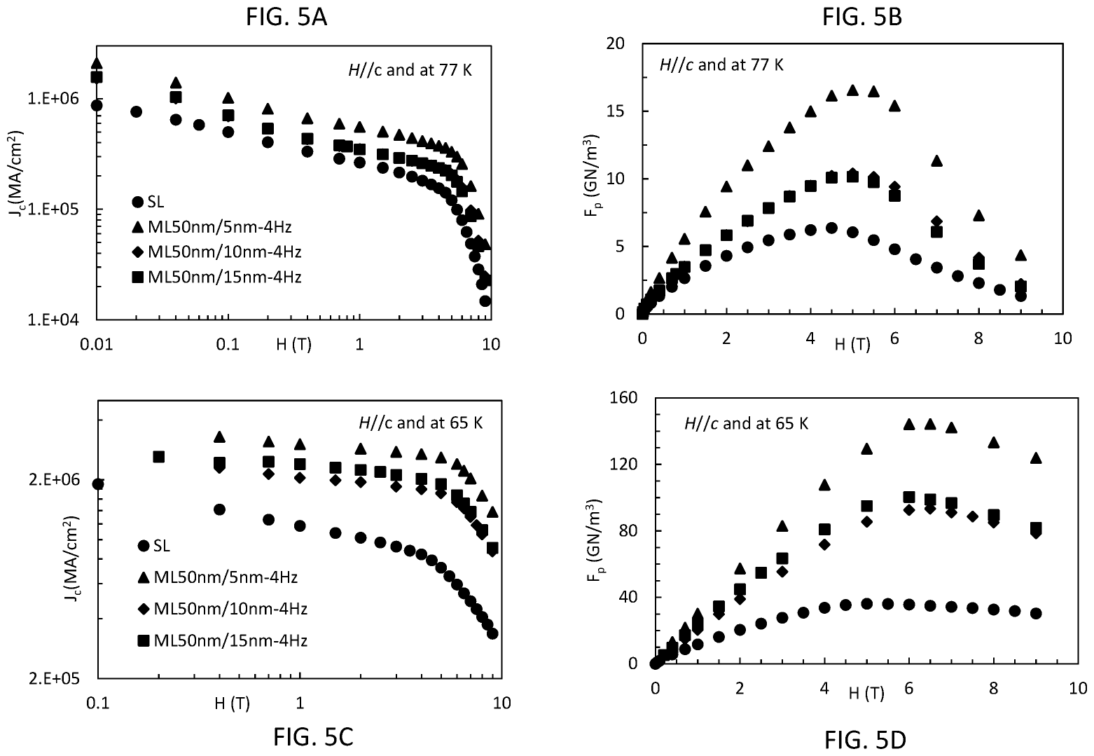

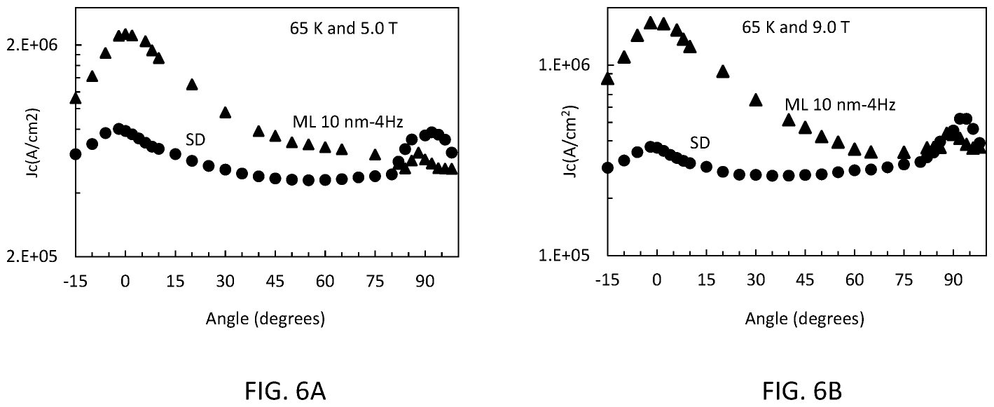

FIGS. 5A-5D show the J_{c}(H) and Fₚ(H) curves of three ML samples: 6% BZO/YBCO ML 50 nm/5 nm-4 Hz, 6% BZO/YBCO ML 50 nm/10 nm-4 Hz, and 6% BZO/YBCO ML 50 nm/15 nm-4 Hz respectively at 77 K and 65 K. Here, the three ML samples had the CaY-123 spacer layers fabricated using the same PLD repetition rate, but different thicknesses. Again, the 6% BZO/YBCO SL reference sample is also included for comparison. All three ML samples have overall higher J_{c}(H) and Fₚ(H) in the entire magnetic field range up to 9.0 T than the SL counterpart. Particularly at 65 K, the enhancement is more pronounced at higher fields. For example, the J_{c}(H) and Fₚ(H) enhancement factors 1.9 and 2.5, respectively, at 1.0 T while they increase to 5 and 4.2, respectively, at 9.0 T. The higher enhancement factors at higher magnetic fields in ML samples with a coherent BZO 1D-APC/YBCO interface also lead to enhanced pinning at H orientations away from H//c-axis (θ=0°) as illustrated in the J_{c}(θ) curves of the ML and SL samples at 65 K as shown in FIGS. 6A-6B. At high fields of 5 T (FIG. 6A) and 9 T (FIG. 6B), the improved pinning in ML samples extends to θ>75°, indicating the BZO 1D-APCs are indeed strong pins with coherent interfaces with YBCO matrix.

The results of FIGS. 4A-4D and FIGS. 5A-5D demonstrate that the defective BZO 1D-APC/YBCO interface has more detrimental impact on high-field pinning efficiency. An interesting observation is that the ML 50 nm/5 nm-4 Hz sample has significantly higher J_{c}(H), Fₚ and Hₘₐₓ than the ML 50 nm/10 nm-4 Hz and ML 50 nm/15 nm-4 Hz. Since the three nanocomposites have an identical T_{c} of 85.0 K and were all made with the same PLD repetition frequency of 4 Hz, the difference in their J_{c}(H) may be attributed to the Ca-diffusion patterns controlled by the CaY-123 spacer layer thickness. However, the observation is surprising since the ML 50 nm/5 nm-4 Hz nanocomposite would be expected to have the smallest driving force for Ca-doping (and thus, least amount of Ca doping) into the BZO 1D-APC/YBCO interface.

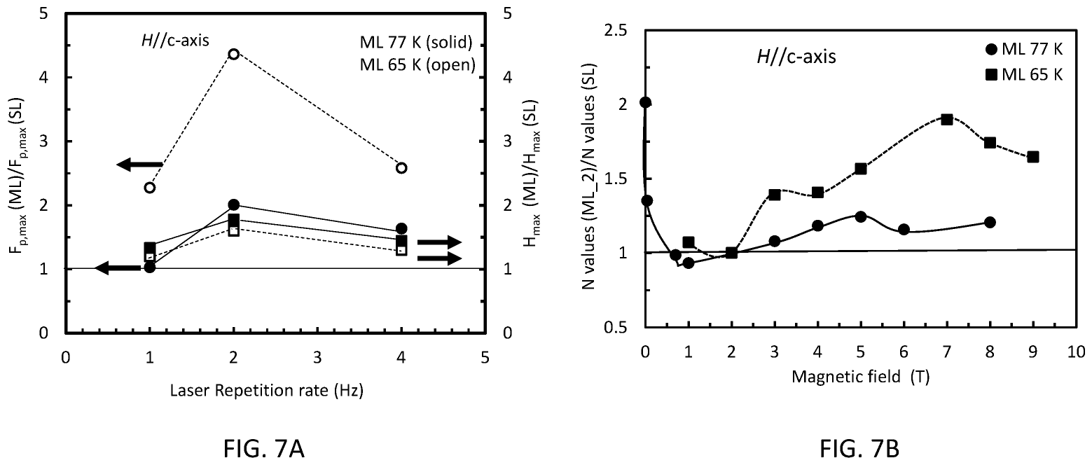

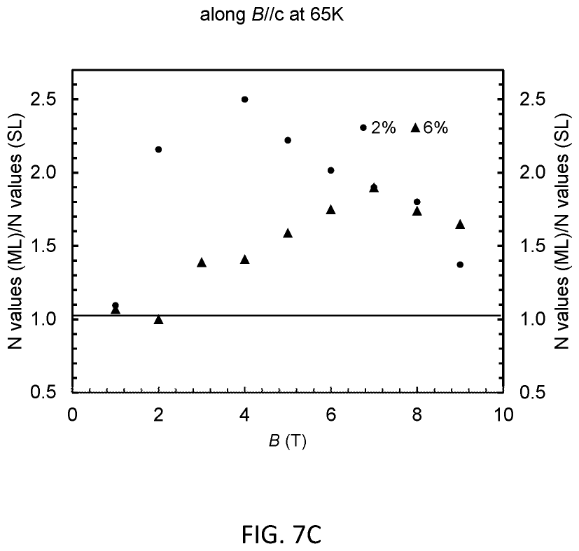

FIG. 7A compares the ratio of F_{p, max}(ML)/_{Fp, max}(SL) and Hₘₐₓ(ML)/Hₘₐₓ(SL) for the ML samples made at different PLD repetition rate at 77 K (solid) and 65 K (open). Overall, the values of the both ratios are in exceed “1”, demonstrating the enhanced pinning efficiency by Ca-doping in ML samples. At 77 K, the F_{p, max} ratio is about 1.03, 2.0 and 1.64 times for ML 50 nm/10 nm-1 Hz, ML 50 nm/10 nm-2 Hz and ML 50 nm/10 nm-4 Hz nanocomposite films respectively as compared to the SL sample. However, at 65 K, this ratio is increased to 2.27, 4.36 and 2.64 times higher for ML 50 nm/10 nm-1 Hz, ML 50 nm/10 nm-2 Hz and ML 50 nm/10 nm-4 Hz films respectively as compared to the SL sample. At both temperatures of 77 K and 65 K, the highest ratio for ML 50 nm/10 nm-2 Hz film suggests that the Ca diffusion has been optimized, maximizing the interface repair and minimizing the T_{c} drop and hence, enhancing the F_{p, max}. As shown in Table 2, the F_{p.max} ˜157.70 GN/m³ for ML 50 nm/10 nm-2 Hz is the highest reported so far at 65 K, and is about 1.30 and 1.53 times higher than the highest claimed F_{p, max} ˜120 GN/m³, ˜103 GN/m³ and 122 GN/m³ for BHO/REBCO, BSO/YBCO and (BaNbOy+Y2O3)/YBCO films respectively. (See Mele, P., et al., Physica C: Superconductivity, 2009. 469(15): p. 1380-1383; Feldmann, D., et al., Superconductor Science and Technology, 2010. 23(9): p. 095004; and Miura, S., et al., Applied Physics Express, 2017. 10(10): p. 103101.)

TABLE 2
Comparison of 1D-APC diameter (D), inter 1D-APC distance (d),
(record high) maximum pinning forces F_{p, max} and matching field
(H* = Φ₀/d²), Hₘₐₓ/H* of BM(=Zr, Sn, Hf))O on RE(=Y, Sm) BCO
single and multilayer thin films in this Example and published works.

| | | Average inter 1D-APC | F_{p,max} (GN/m³) | | Hmax/H* at | |
|---|---|---|---|---|---|---|
| Sample info | D (nm) | distance d (nm) | at 65 K | H* (T) | 65 K | Ref. |
| 2% BZO/YBCO | 5.0-6.0 | Approx. 20.0 | 74.0 | 6.0 | 0.83 | a |
| 6% BZO ML50 nm/ | 5.0-6.0 | 12.0 | 157.0 | 14.3 | 0.56 | This Example |
| 10 nm-2 Hz | | | | | | |
| 3.8% BHO/SmBCO | 5.0-6.0 | Not provided | 120.0 | 6.0 | 0.83 | b |
| 3.48% BSO/YBCO | 8.4 | 21.0 | 103.0 | 4.8 | 0.63 | c |
| 5.0 mol. % BaNbOy + | 10-15 | Not provided | 122.0 | 2.0 | 2.5 | d |
| 5.0 mol. % Y₂O₃/YBCO | | | | | | |

a Wee, S.H., et al., Scientific reports, 2013. 3: p. 2310;
b Miura, S., et al., Applied Physics Express, 2017. 10(10): p. 1031011;
c Mele, P., et al., Physica C: Superconductivity, 2009. 469(15): p. 1380-1383; and
d Feldmann, D., et al., Superconductor Science and Technology, 2010. 23(9): p. 095004.

The results of FIG. 7A also show that the Ca diffusion at APC/YBCO interface is laser repetition rate dependent. For example, at 77 K, ratio of Hₘₐₓ ˜1.33 and 1.44 for ML 50 nm/10 nm-1 Hz and ML 50 nm/10 nm-4 Hz films is lower than that of the ratio of Hₘₐₓ ˜1.78 for ML 50 nm/10 nm-2 Hz. At 65 K, although the ratio of Hₘₐₓ follows the similar trend, the values are decreased to 1.2, 1.6, and 1.3 for ML 50 nm/10 nm-1 Hz, ML 50 nm/10 nm-2 Hz, and ML 50 nm/10 nm-4 Hz films, respectively.

FIG. 7B shows the ratio of the N value of the ML 50 nm/10 nm-2 Hz and SL films with respect to the applied field orientation of H//c-axis at 77 K and at 65 K. The N value is a quantitative evaluation of the pinning potential of the superconducting thin films. The N value, calculated from I-V curves derived from the relation V∝I^{-α} (Civale, L., et al., IEEE transactions on applied superconductivity, 2005. 15(2): p. 2808-2811), is proportional to the pinning potential energy. Overall ML 50 nm/10 nm-2 Hz film shows strong pinning potential that increases with H and reaches a maximum at Hₘₐₓ (˜5.0 T) at 77 K. The slightly lower values in the field range of 0.7-1.0 T might be due to the higher thermal effect. A similar trend is observed at 65 K as well although the ratios are overall higher at 65 K as compared to 77 K. At 77 K, the pinning potential of the ML sample is about 25% higher on average for all fields from 0-9.0 T. The lowest enhancement in pinning potential is about 16% at 4.0 T and the highest enhancement is about 31% at 8.0 T, which is close to Hₘₐₓ, and remains constant at 2.0 T as temperature decreases from 77 K to 65 K. Since the N values correlate with J_{c} values, the higher ratio of N values is consistent with higher J_{c}(H) values and reveals the difference of decreasing trend of the J_{c}(H) curves at 77 K and 65 K for these samples. FIG. 7C shows the magnetic field dependence of the N values of the 2% and 6% BZO/YBCO ML samples to the N values normalized to that of their SL counterparts at B//c and 65K. The ML samples were those of ML 50 nm/10 nm-2 Hz.

### Conclusion

In this work, a dynamic Ca/Cu cation replacement approach was developed to prevent the formation of defective, semi-coherent BZO 1D-APC/YBCO interface due to large lattice mismatch between the two materials. Specifically, the CaY-123 spacers of 5-15 nm in thickness were inserted to form 6 vol. % BZO+YBCO/CaY-123 ML nanocomposite films, in which the Ca diffusion into the tensile strained YBCO induced by the BZO 1D-APCs enabled elongation of the c-axis of YBCO due to a partial replacement of Cu on the YBCO lattice. This allowed a dynamic reduction of the BZO 1D-APC/YBCO interfacial strain before interfacial defects formation, leading to a highly coherent BZO 1D-APC/YBCO interface. The elongated c-axis lattice constant from 1.17 nm in original YBCO to 1.24 nm in the YBCO with the Ca/Cu replacement and the coherent BZO 1D-APC/YBCO interface of lattice mismatch reduced from ˜8-9% to 2% were confirmed in microstructure analysis using HRTEM. A significantly improved pinning efficiency was been obtained in ML samples. For example, J_{c}(H) at 9.0 T at both 77 and 65 K were five times greater for the ML samples as compared to the SL sample. In addition, the peak pinning force density F_{p, max} ˜157 GN/m³ at Hₘₐₓ ˜8.0 T and 65 K from a ML sample represents 4.4 times increase over the SL sample (SL sample has F_{p, max} ˜36 GN/m³ (only at Hₘₐₓ ˜5.0 T)). The much enhanced pinning efficiency of the BZO 1D-APCs indicates the critical importance in achieving a coherent APC/YBCO interface APCs/YBCO nanocomposites.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

The foregoing description of illustrative embodiments of the disclosure has been presented for purposes of illustration and of description. It is not intended to be exhaustive or to limit the invention to the precise form disclosed, and modifications and variations are possible in light of the above teachings or may be acquired from practice of the disclosure. The embodiments were chosen and described in order to explain the principles of the disclosure and as practical applications of the invention to enable one skilled in the art to utilize the invention in various embodiments and with various modifications as suited to the particular use contemplated. It is intended that the scope of the disclosure be defined by the claims appended hereto and their equivalents.

1. A superconducting nanocomposite comprising a high temperature superconductor (HTS); a plurality of artificial pinning centers (APCs) in the form of one-dimensional (1D) nanorods distributed throughout the HTS and oriented parallel to a c-axis of the HTS, each APC composed of a non-superconducting material and surrounded by the HTS, thereby forming an APC-HTS interface; and one or more repair regions composed of a repair material comprising a cation A, wherein a portion of the cation A of the repair material has diffused out of the one or more repair regions and into the HTS.

2. The superconducting nanocomposite of claim 1, wherein each repair region is region in direct contact with at least one APC-HTS interface.

3. The superconducting nanocomposite of claim 1, wherein the HTS and the non-superconducting material have a lattice mismatch of at least 7%.

4. The superconducting nanocomposite of claim 1, wherein the HTS has formula (RE)Ba₂Cu₃O₇₋ₓ, wherein RE is selected from Sc, Y, and lanthanides.

5. The superconducting nanocomposite of claim 1, wherein the HTS is YBa₂Cu₃O₇₋ₓ.

6. The superconducting nanocomposite of claim 1, wherein the non-superconducting material is a perovskite selected from BaZrO₃, YBa₂NbO₆, BaSnO₃, BaHfO₃, SrZrO₃, SrHfO₃, CaSnO₃, and CaHfO₃.

7. The superconducting nanocomposite of claim 1, wherein the non-superconducting material is BaZrO₃.

8. The superconducting nanocomposite of claim 1, wherein the repair material is composed of (A_{y})(RE_{1-y})Ba₂Cu₃O₇₋ₓ, wherein RE is selected from Sc, Y, and lanthanides and the cation A is different from RE.

9. The superconducting nanocomposite of claim 8, wherein A is Ca.

10. The superconducting nanocomposite of claim 1, wherein the HTS has formula (RE)Ba₂Cu₃O₇₋ₓ, wherein RE is selected from Sc, Y, and lanthanides; the non-superconducting material is a perovskite selected from BaZrO₃, YBa₂NbO₆, BaSnO₃, BaHfO₃, SrZrO₃, SrHfO₃, CaSnO₃, and CaHfO₃; and the repair material is composed of (A_{y})(RE_{1-y})Ba₂Cu₃O₇₋ₓ, wherein RE is selected from Sc, Y, and lanthanides and the cation A is different from RE.

11. The superconducting nanocomposite of claim 10, wherein the HTS is YBa₂Cu₃O₇₋ₓ; the non-superconducting material is BaZrO₃; and A is Ca.

12. The superconducting nanocomposite of claim 1, wherein the one or more repair regions are in the form of one or more layers embedded within the HTS having the plurality of APCs distributed throughout.

13. The superconducting nanocomposite of claim 12, wherein the one or more layers of repair regions each have an average thickness in a range of from 1 nm to 12 nm.

14. The superconducting nanocomposite of claim 13, wherein the HTS having the plurality of APCs distributed throughout are also in the form of one or more layers each having an average thickness in a range of from 25 nm to 100 nm.

15. The superconducting nanocomposite of claim 14, wherein the one or more layers of repair regions each have an average thickness in a range of from 1 nm to 3 nm and the one or more layers of HTS having the plurality of APCs distributed throughout each have an average thickness in a range of from 40 nm to 60 nm.

16. The superconducting nanocomposite of claim 15, wherein the HTS is YBa₂Cu₃O₇₋ₓ; the non-superconducting material is BaZrO₃; and A is Ca.

17. A method of making a superconducting nanocomposite, the method comprising:
depositing an APC-HTS nanocomposite material comprising a HTS and a non-superconducting material onto a surface of a substrate under conditions to form a plurality of APCs in the form of 1D nanorods distributed throughout the HTS and oriented parallel to a c-axis of the HTS, each APC composed of the non-superconducting material and surrounded by the HTS, thereby forming an APC-HTS interface; and
depositing a repair material composed of a repair material comprising a cation A to form one or more repair regions, and under conditions so that a portion of the cation A of the repair material diffuses out of the one or more repair regions and into the HTS.

18. The method of claim 17, wherein each repair region is in direct contact with at least one APC-HTS interface.

19. The method of claim 17, wherein the depositing is carried out using pulsed laser deposition (PLD).

20. (canceled)

21. (canceled)

22. A method of using the superconducting nanocomposite of claim 1, the method comprising exposing the superconducting nanocomposite to a magnetic field at a temperature below the superconducting nanocomposite's T_{c}.
